(19) United States
(12) Patent Application Publication
(10) Pub. No.: US 2013/0237055 A1
(43) Pub. Date: Sep. 12, 2013

(54) METHOD OF REDISTRIBUTING FUNCTIONAL ELEMENT

(71) Applicants: Takuo Funaya, Tokyo (JP); Francois Iker, Mont-Saint-Guibert (BE); Eric Beyne, Leuven (BE)

(72) Inventors: Takuo Funaya, Tokyo (JP); Francois Iker, Mont-Saint-Guibert (BE); Eric Beyne, Leuven (BE)

(73) Assignees: IMEC, Leuven (BE); NEC CORPORATION, Tokyo (JP)

(21) Appl. No.: 13/703,430

(22) PCT Filed: Jun. 10, 2011
(86) PCT No.: PCT/JP2011/063856

§ 371 Date: May 24, 2013

(30) Foreign Application Priority Data
Jun. 11, 2010 (JP) 2010-133785

(51) Int. Cl. H01L 21/48

(52) U.S. Cl. CPC H01L 21/486
USPC 438/672

(57) ABSTRACT

According to a method of redistributing a functional element of the present invention, an insulating resin layer is supplied onto a functional element wafer such as an LSI. A portion to be a via hole on an electrode pad of the functional element is filled with a sacrificial layer. The top of the sacrificial layer filled in the via hole is exposed from the insulating layer by grinding or polishing. Therefore, it is possible to prevent breakage of a brittle material such as a low-k material in the functional element, which would be caused by transmission of shearing stress when a conventional pillar or a conventional gold projecting electrode is used. The reliability, the yield, and the level of flatness can be improved by forming an interconnection conductive layer after the flattening process of grinding or polishing. Accordingly, a fine conductive interconnection can be formed.

### TECHNICAL FIELD

The present invention relates to a method of redistributing or rewiring a functional element, and more particularly to a method of redistributing or rewiring a functional element that can reduce influence of stress produced in an internal element during a surface flattening process.

### BACKGROUND ART

Recent functional elements have been miniaturized with improved performance and advanced functions. A redistribution conductive layer has been added to a miniaturized functional element in order to rewire the functional element and to achieve a higher packaging density. Thus, size reduction of electronic equipment has been achieved. It is to be noted throughout the instant specification that the term “redistributing” is used to specify rewiring for repetition of wiring.

The following patent documents disclose a method of redistributing or rewiring a functional element. For example, Japanese Patent No. 4057146 and Japanese laid-open patent publication No. 2007-53395 disclose that pillars or gold projecting electrodes are formed with a predetermined height on an electrode pad formed on an underlying substrate and on an electrode pad of a semiconductor device mounted on the substrate. Then an insulating resin layer is provided on the entire surface of the structure. Thereafter, the copper (Cu) pillars or the gold projecting electrodes that have been covered with the insulating resin layer is polished such that only upper portions of the pillars and the projecting electrodes are exposed so as to serve as a terminal. In a subsequent process, an interconnection conductive layer is formed on the insulating resin layer by using an electrolytic plating method such that it is connected to the exposed gold or copper terminals.

For example, according to Japanese laid-open patent publication No. 2008-300559, an insulating resin layer is formed after a semiconductor device has been mounted on an underlying substrate. Via holes are formed in the insulating resin layer on an electrode pad. An interconnection conductive layer is formed on upper surfaces of the electrode pad and the insulating resin layer by an electrolytic plating method or the like.

### DISCLOSURE OF THE INVENTION

However, the aforementioned technology disclosed in the patent documents has the following problems. A first problem is that stress is applied to a circuit layer within a semiconductor device during a surface flattening process. As a result, a low-k layer (interlayer dielectric having a low dielectric constant) is broken. For example, according to Japanese Patent No. 4057146 and Japanese laid-open patent publication No. 2007-53395, an insulating resin layer includes therein copper (Cu) pillars or gold projecting bumps on an electrode pad of a semiconductor device. The electrode that has been covered with the insulating resin is polished such that only an upper portion of the electrode is exposed so as to serve as a terminal. At that time, as shown in a cross-sectional structure of FIG. 5, shearing stress is applied to a circuit layer inside of a semiconductor device 101 through a metal pillar 104 or a projecting bump by a polishing wheel or a grinder 106. As a result, a low-k layer (interlayer dielectric having a low dielectric constant) 102 is problematically broken. Furthermore, defects such as crack are produced inside of the semiconductor device, resulting in poor reliability of a product.

A second problem is that the manufacturing yield is lowered by open defects produced after the formation of the interconnection conductive layer because a seed layer is discontinuously formed at some locations. For example, according to Japanese laid-open patent publication No. 2008-300559, some steps are produced on a surface of an insulating resin layer around a location at which a semiconductor device has been located. This becomes significant when a resin is supplied by a spin coating method. Accordingly, when an interconnection is formed with a width of 20 μm or less and a thickness of 20 μm or less, patterning defects are likely to occur in exposure and development of a photoresist, resulting in a lowered manufacturing yield. Furthermore, if a via hole has a small inside diameter of 30 μm or less and an aspect ratio higher than 1, a seed layer is likely to be formed discontinuously on a side wall and a bottom of the via hole at the time of supply of the plating seed layer. Thus, the manufacturing yield is problematically lowered by open defects produced after the formation of the interconnection conductive layer.

The present invention has been made in view of the above problems. It is, therefore, an object of the present invention to obtain surface flatness of an insulating resin, which is effective in formation of an interconnection conductive layer, by using a polishing or grinding process. Another object of the present invention is to provide a product that can prevent damage to an internal interconnection structure of a functional element due to application of stress and can have high reliability and yield.

According to one aspect of the present invention, there is provided a method of redistributing a functional element, the method comprising:

a first step of forming an insulating layer on a functional element and then forming a via hole in the insulating layer for thereby forming a via hole on an electrode pad of the functional element;

a second step of filling the via hole with a sacrificial layer;

a third step of flattening a surface above the functional element so as to expose the sacrificial layer in the via hole;

a fourth step of removing the sacrificial layer in the via hole so as to expose the electrode pad in the via hole; and

a fifth step of connecting a interconnection conductive layer to the exposed electrode pad in the via hole.

According to another aspect of the present invention, there is provided a method of redistributing a functional element, the method comprising:

a first step of forming at least one interconnection layer on a base substrate;

a second step of mounting a functional element on the base substrate;

a third step of forming an insulating layer on the base substrate including the mounted functional element and then forming a via hole in the insulating layer for thereby forming a via hole on an electrode pad of the functional element;

a fourth step of filling the via hole with a sacrificial layer;

a fifth step of flattening a surface above the functional element so as to expose the sacrificial layer in the via hole;

a sixth step of removing the sacrificial layer in the via hole so as to expose the electrode pad in the via hole; and

a seventh step of connecting a interconnection conductive layer to the exposed electrode pad in the via hole.

According to another further aspect of the present invention, there is provided a method of redistributing a functional element, the method comprising:

a first step of forming a sacrificial layer pillar on an electrode pad of a functional element;

a second step of forming an insulating layer on an entire surface of the functional element including the sacrificial layer pillar;

a third step of flattening a surface of the insulating layer so as to expose the sacrificial layer pillar;

a fourth step of removing the exposed sacrificial layer pillar so as to form a via hole on the electrode pad; and

a fifth step of connecting an interconnection conductive layer to the electrode pad of the functional element via the via hole.

According to another further aspect of the present invention, there is provided a method of redistributing a functional element, the method comprising:

a first step of forming at least one interconnection layer on a base substrate;

a second step of forming a sacrificial layer pillar on an electrode pad of a functional element;

a third step of mounting the functional element on which the sacrificial layer pillar has been formed on the base substrate;

a fourth step of forming an insulating layer on the base substrate so as to cover the mounted functional element;

a fifth step of flattening a surface of the insulating layer so as to expose the sacrificial layer pillar;

a sixth step of removing the exposed sacrificial layer pillar so as to expose the electrode pad; and

a seventh step of connecting a interconnection conductive layer to the exposed electrode pad of the functional element.

According to a method of redistributing a functional element of the present invention, an insulating layer is supplied onto a functional element. A flattening process is performed in a state in which a portion to be a via hole on an electrode pad of the functional element has been filled with a sacrificial layer. Then a conductive layer for redistribution that is connected to the electrode pad of the functional element is formed. According to the present invention, the sacrificial layer relaxes shearing stress applied to the electrode pad during a flattening process of polishing or grinding. Therefore, it is possible to prevent damage to an internal interconnection of the functional element. Accordingly, it is possible to prevent breakage of a brittle material such as a low-k material in the functional element, which would be caused by transmission of shearing stress when conventional pillars or gold projecting electrodes are used. A fine interconnection conductive layer can be formed with a high level of flatness after removal of the sacrificial layer. Thus, it is possible to obtain a method of redistributing a functional element that has excellent reliability and a high yield.

### BRIEF DESCRIPTION OF THE DRAWINGS

FIGS. 1(a) to 1(e) are schematic cross-sectional views (Part 1) of processes showing a manufacturing method according to a first embodiment of the present invention.

FIGS. 1(f) to 1(j) are schematic cross-sectional views (Part 2) of processes showing the manufacturing method according to the first embodiment of the present invention.

FIGS. 2(a) to 2(e) are schematic cross-sectional views (Part 1) of processes showing a manufacturing method according to a second embodiment of the present invention.

FIGS. 2(f) to 2(j) are schematic cross-sectional views (Part 2) of processes showing the manufacturing method according to the second embodiment of the present invention.

FIGS. 3(a) to 3(d) are schematic cross-sectional views (Part 1) of processes showing a manufacturing method according to a third embodiment of the present invention.

FIGS. 3(e) to 3(h) are schematic cross-sectional views (Part 2) of processes showing the manufacturing method according to the third embodiment of the present invention.

FIGS. 4(a) to 4(d) are schematic cross-sectional views (Part 1) of processes showing a manufacturing method according to a fourth embodiment of the present invention.

FIGS. 4(e) to 4(f) are schematic cross-sectional views (Part 2) of processes showing the manufacturing method according to the fourth embodiment of the present invention.

FIG. 5 is a schematic cross-sectional view showing exposing a top of a metal pillar according to a conventional grinding method.

### DETAILED DESCRIPTION OF THE EXEMPLARY EMBODIMENTS

A semiconductor having an interconnection formed on silicon (Si), gallium arsenide (GaAs), lithium tantalate (LiTaO₃), lithium niobate (LiNbO₃), crystal, or the like, a microelectromechanical system, which is hereinafter abbreviated to MEMS, a surface acoustic wave (SAW) filter, a thin film functional element, and the like, a printed board such as a condenser, a resistance, or an inductor, and a flexible substrate having an interconnection formed thereon are suitably used for a functional element according to the present invention. However, the functional element is not limited to those specific examples. A functional element, a semiconductor such as silicon, glass, alumina, glass-ceramic, ceramic such as titanium nitride or aluminum nitride, metals such as copper, stainless, iron, and nickel, and an organic resin such as a polyimide sheet or an epoxy sheet are suitably used for the base substrate. However, the base substrate is not limited to those specific examples.

A UV-YAG laser, a CO₂ laser, and the like are suitably used to open a via hole in an insulating resin layer. However, the method of opening the via hole is not limited to those specific examples. When the insulating resin layer is photosensitive, the via hole can be opened by exposure and development. Furthermore, the via hole can also be opened by dry etching.

According to the present invention, copper (Cu), nickel (Ni), gold (Au), silver (Ag), tin-silver (Sn—Ag) solder, and the like are used for portions of an interconnection conductive layer that are exposed on a surface thereof. For example, even if an interconnection conductive layer is formed by using copper-plating, the interconnection conductive layer can suitably be formed by formation of a seed layer deposited by electroless plating or sputtering, together with an electrolytic plating process, a printing process, a reflow process, and the like. However, the material of the surface of the interconnection conductive layer is not limited to those specific examples. Copper, nickel, gold, silver, and Sn—Ag are also suitably used for metal pillars located near a side surface of the mounted functional element. However, the material of the metal pillars is not limited to those specific examples. Metal pillars can be formed by plating. After conductive paste is printed, a high-temperature treatment may be performed to integrally form metal within the via hole.

Furthermore, a solder resist layer having openings formed only at necessary locations can suitably be formed on the uppermost surface of a circuit board including a functional element according to the present invention. Since the necessary locations are covered with the solder resist layer, it is possible to regulate interconnection conductive portions exposed on a surface of the structure, to prevent oxidation of interconnections, and to prevent a short circuit between conductive electrode interconnections at the time of mounting with a solder. Furthermore, it is possible to form an interconnection conductive layer that can prevent oxidation and has high solder wettability when soldering with copper, nickel, gold, silver, Sn—Ag, or the like, electroless plating, electrolytic plating, printing, or the like is conducted on the interconnection conductive layer exposed in the openings.

A buildup in which insulating layers and interconnection conductive layers are alternately formed on opposite surfaces in such a state that the interconnection conductive layers are connected to each other by a via hole for multilayered interconnections can be formed in a substrate including a functional element according to the present invention. The present invention covers such a multilayered circuit board including a functional element, an electronic part mounted to another circuit board or functional element after individual dicing, and a substrate having such a substrate including a functional element.

### First Embodiment

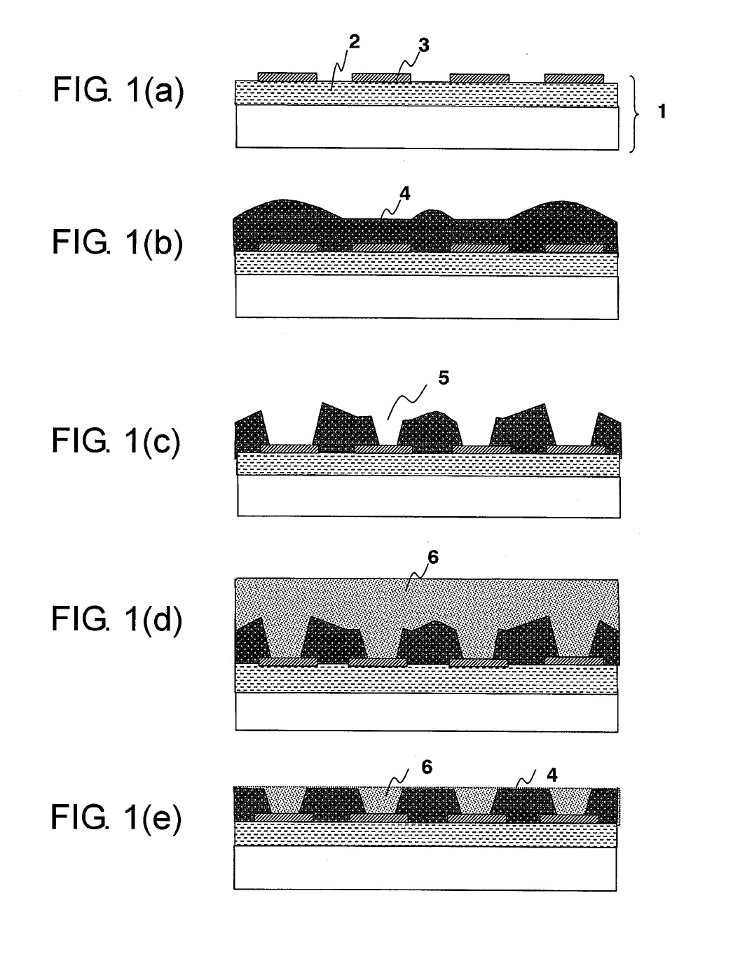

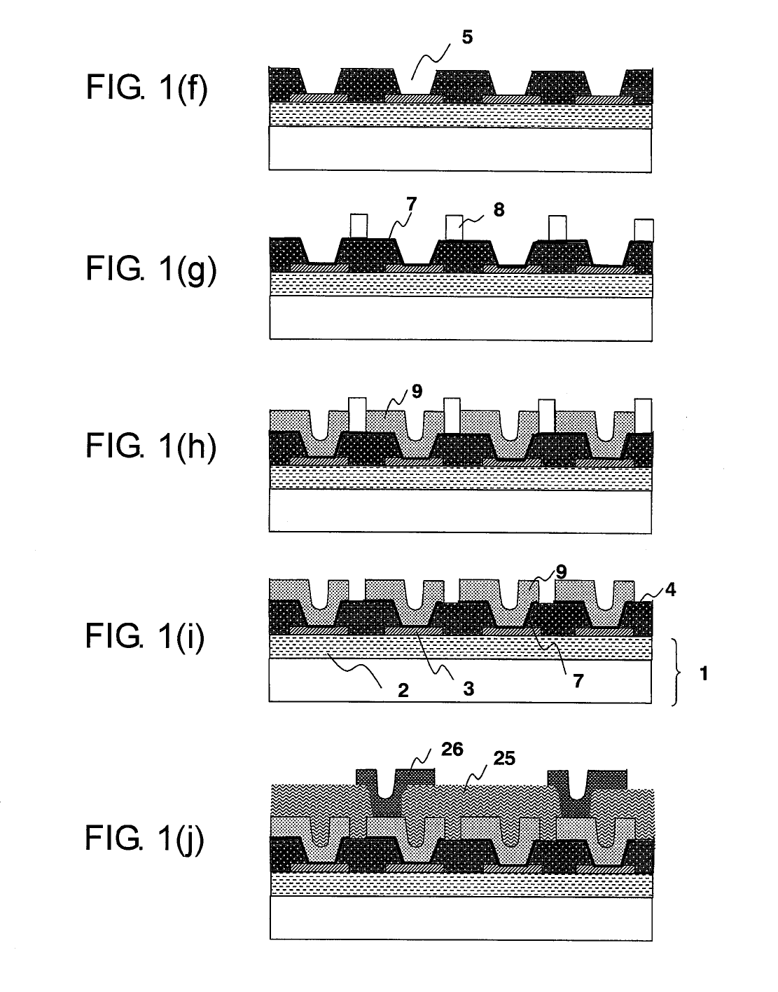

Embodiments of the present invention will be described in detail with reference to the drawings. FIGS. 1(a) to 1(e) and 1(f) to 1(j) are schematic cross-sectional views showing processes of a manufacturing method according to a first embodiment of the present invention.

FIG. 1(a) shows a structure of a functional element 1, an internal interconnection layer 2 of the functional element, and electrode pads 3 provided on the uppermost portion of the internal interconnection layer 2. In FIG. 1(b), an insulating layer 4 is formed. A spin coating method, a curtain coating method, a printing method, a laminating method, and the like are suitably used to supply the insulating layer 4. However, the method of supplying the insulating layer 4 is not limited to those specific examples. Then, for example, in a case where the insulating layer 4 is formed of an insulating resin layer, resin may be cured as needed with an oven, a hot plate, or the like. Inorganic substance can be used for the insulating layer instead of the insulating resin layer. For the inorganic insulating layer, silicon dioxide (SiO₂), silicon nitride (Si₃N₄), silicon oxynitride (SiON), and the like are suitably used. However, the inorganic insulating layer is not limited to those specific examples. A spin coating method, a chemical vapor deposition (CVD) method, a physical vapor deposition (PVD) method, and the like are suitably used to supply the inorganic insulating layer. However, the method of supplying the inorganic insulating layer is not limited to those specific examples. At that time, irregularities are formed on the organic resin layer or the inorganic layer as the insulating layer due to a surface structure of the functional element 1.

FIG. 1(c) shows a subsequent step of forming via holes 5 in the insulating layer 4. The via holes 5 are formed so that part of the electrode pads 3 is exposed. In a case where the insulating layer 4 is made of a photosensitive material, the via holes 5 are suitably formed by exposure and development. In a case where the insulating layer 4 is made of a non-photosensitive material, the via holes 5 are suitably formed by using a resin mask or a metal mask and dry-etching or wet-etching using a solvent or the like. However, the method of forming the via holes 5 is not limited to those specific examples. The irregularities generated in FIG. 1(b) still remain after the via holes 5 have been formed in FIG. 1(c).

In a subsequent process of FIG. 1(d), a sacrificial layer 6 is supplied so that the via holes are filled with the sacrificial layer 6. A spin coating method, a curtain coating method, a printing method, a laminating method, and the like are suitably used to supply the sacrificial layer 6. However, the method of supplying the sacrificial layer 6 is not limited to those specific examples. Then the thickness of the entire structure or the thickness of the sacrificial layer 6 is measured by using a contact probe, a micrometer, or an ellipsometer. The sacrificial layer 6 is ground or polished by a predetermined thickness. Thus, an upper portion of the sacrificial layer 6 is removed from a surface of the structure such that upper surfaces of the sacrificial layer 6 within the via holes and upper surfaces of the insulating layer 4 around the sacrificial layer 6 are flattened as shown in FIG. 1(e). Thus, the surfaces of the insulating layer 4 and the sacrificial layer 6 are flattened on the same level. The state in which the upper surfaces (tops) of the sacrificial layer 6 are leveled with the upper surfaces of the insulating layer 4 around the sacrificial layer 6 is referred to as a state of exposing the tops of the sacrificial layer 6 from the insulating layer 4 around the sacrificial layer 6.

A buffing machine, a grinder, a surface planer (grinding machine or cutting machine), a chemical mechanical polisher (CMP), and the like are suitably used as a polishing or grinding device in the flattening step of flattening the surfaces of the sacrificial layer 6 and the insulating layer 4. However, the polishing or grinding device is not limited to those specific examples. Those machines are selected depending upon the grinding thickness, the allowable height control precision, the allowable surface roughness, and contents of the sacrificial layer 6 and the insulating layer 4. According to the present invention, the filled sacrificial layer 6 relaxes shearing stress applied to the electrode pads 3 in the polishing or grinding process. Therefore, it is possible to prevent damage to an internal interconnection of the functional element 1. Accordingly, the yield and the reliability of the product can be enhanced.

Subsequently, the sacrificial layer 6 filled in the via holes 5 is removed so that the via holes 5 are opened in the cross-sectional structure of FIG. 1(f). A removal method of a wet process using a chemical agent including a solvent component of the sacrificial layer 6 or the like is suitably used to remove the sacrificial layer 6. However, the method of removing the sacrificial layer 6 is not limited to that specific example. In order to remove a residue of the sacrificial layer 6, it is effective to add an oxygen plasma ashing process for cleaning or the like after the removal process. Furthermore, cleaning with a weak acid is effective in removing an oxide film formed on the surfaces of the electrode pads 3. In order to maintain the adhesiveness between the interconnections and the insulating layer 4 in the subsequent plating step, it is effective to roughen the inner surfaces of the via holes 5 and the surface of the insulating layer 4 by using a desmear process.

FIG. 1(g) shows a cross-sectional structure in which, after a seed layer 7 is supplied onto the structure of FIG. 1(f) by a vapor deposition method or an electroless plating method, a photoresist is supplied by a laminating method, a spin coating method, a spray coating method, or the like, and a photoresist layer 8 is then patterned by UV exposure and development. The seed layer 7 is formed of a single layer or multiple layers of metal such as titanium (Ti), copper (Cu), and palladium (Pd). However, the structure of the seed layer 7 is not limited to those specific examples. Subsequently, opened portions of the photoresist layer 8 are plated with a metal conductor having a desired thickness by an electrolytic plating method or an electroless plating method. Thus, an interconnection conductive layer 9 is formed as a conductive layer for redistribution as shown in a cross-sectional structure of FIG. 1(h). After the plating process, the photoresist layer 8 is removed. The exposed seed layer 7 is etched, so that the electrode interconnection layer 9 can be provided on the insulating layer 4 via the seed layer 7 as shown in FIG. 1(i).

FIG. 1(j) is a schematic cross-sectional view showing that an insulating layer 25 and an interconnection conductive layer 26 are formed for further multilayering by using a semi-additive method after the formation of the conductive layer for redistribution according to the present invention in FIG. 1(i). At that time, it is preferable to form a plating seed layer between the insulating layer 25 and the interconnection conductive layer 26 in order to improve the adhesiveness. For this seed layer, Ti, Pd, Cu, and the like are suitably used. However, the material of the seed layer is not limited to those specific examples. Furthermore, according to the present invention, the insulating layer and the interconnection conductive layer can further be multilayered by a semi-additive method, an additive method, a lift-off method, and the like. The interconnection conductive layer 9 and the interconnection conductive layer 26 are conductive layers for redistributing the functional element. Therefore, the interconnection conductive layer 9 and the interconnection conductive layer 26 can be referred to as redistribution conductive layers or rewiring conductive layers. Furthermore, the uppermost surface of the interconnection conductive layer 9 and the interconnection conductive layer 26 are conductive layers that serve as a connection electrode to the exterior of the functional element. Therefore, the uppermost surface of the interconnection conductive layer 9 or the interconnection conductive layer 26 can be referred to as electrode interconnection conductive layers.

According to a redistribution method of the present embodiment, an insulating layer is formed on a functional element, and a via hole is defined in the insulating layer on an electrode pad of the functional element. In a state in which the via hole has been filled with a sacrificial layer, the insulating layer and the sacrificial layer are flattened. The sacrificial layer in the via hole is removed. An interconnection conductive layer is formed so that the via hole is filled with the interconnection conductive layer. Thus, a redistribution or rewiring conductive layer is formed. Thereafter, an insulating layer and an interconnection conductive layer may alternately be formed so as to provide a multilayered interconnection. Furthermore, a solder resist, a metal bump, or the like may be formed for a final product.

In a polishing or grinding process according to the present invention, a relaxation layer relaxes shearing stress applied to the electrode pad. Therefore, it is possible to prevent damage to an internal interconnection of the functional element. Accordingly, it is possible to provide a functional element product having excellent yield and reliability.

### Second Embodiment

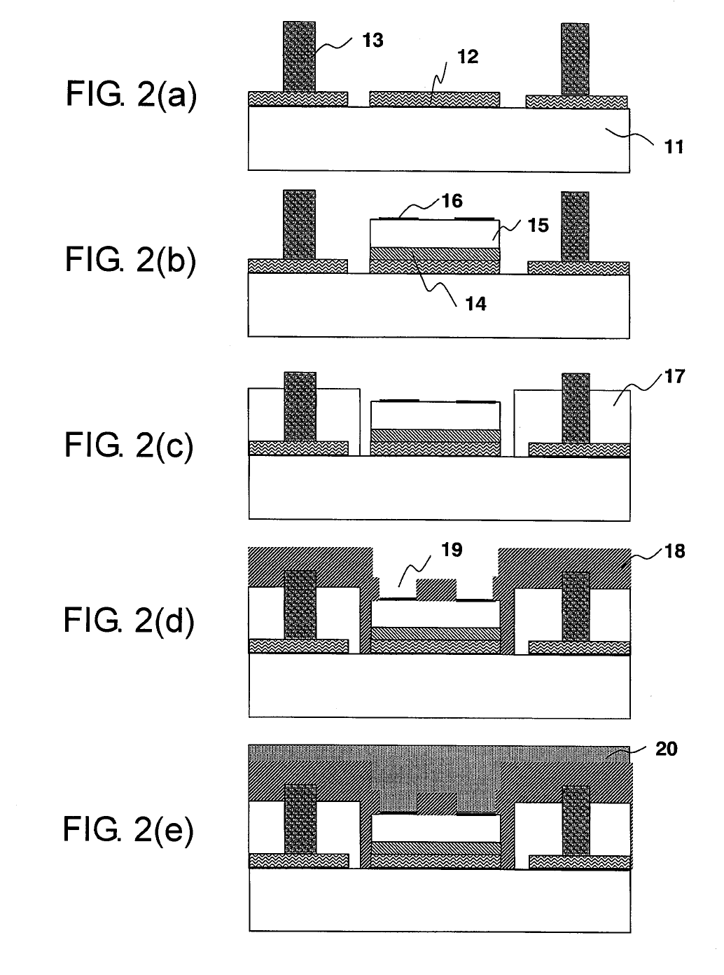

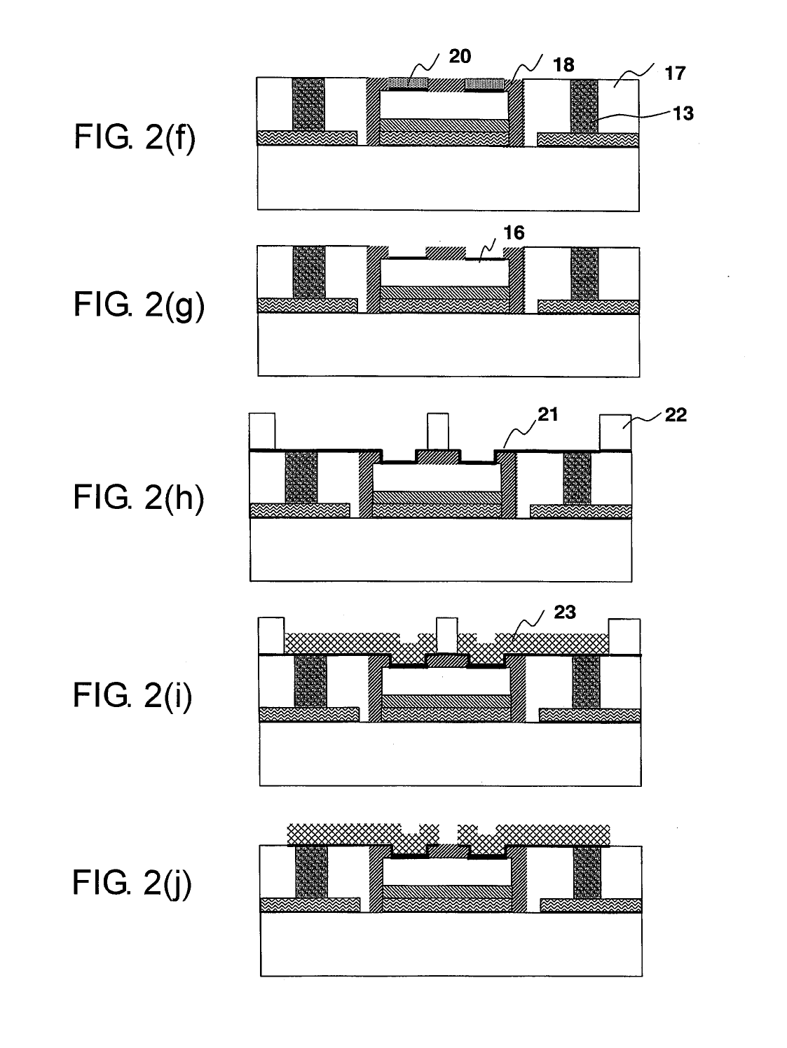

FIGS. 2(a) to 2(e) and 2(f) to 2(j) are schematic cross-sectional views showing processes of a manufacturing method according to a second embodiment of the present invention.

FIG. 2(a) shows a structure in which, after an interconnection layer 12 is formed on a base substrate 11, metal pillars 13 are formed on the interconnection layer 12. Metals such as Cu and stainless, glass substrates, alumina substrates, Si, and the like are suitably used for the base substrate according to the present invention. However, the material of the base substrate is not limited to those specific examples. Furthermore, from the viewpoint of electric characteristics, it is preferable to provide an insulating layer between the base substrate 11 and the interconnection layer 12 in a case where the base substrate 11 is a conductor or a semiconductor. In a case where the base substrate 11 is a functional element, the metal pillars 13 provided right above electrode pads via the interconnection layer 12 may cause damage to the interior of the functional element. Therefore, it is not preferable to provide the metal pillars 13 right above the electrode pads from the viewpoint of a subsequent grinding or polishing process. In such a case, the positions of the electrode pads are deviated from the interconnection layer 12 so that the electrode pads do not overlap the metal pillars. Copper, gold, Sn—Ag, Sn, and the like are suitably used for the metal pillars 13. However, the material of the metal pillars 13 is not limited to those specific examples. A method of forming a projecting electrode by plating or heating a gold wire, printing of metal paste, a reflow method, and the like are suitably used as a method of manufacturing the metal pillars 13. However, the method of manufacturing the metal pillars 13 is not limited to those specific examples.

FIG. 2(b) shows a structure in which a functional element 15 is provided at a predetermined position in the structure of FIG. 2(a) via an adhesive layer 14 in a state in which a circuit surface faces upward. In this case, the functional element 15 may not be connected or bonded to the interconnection layer 12 via the adhesive layer 14 and may be connected and bonded directly to the base substrate 11. At that time, electrode pads 16 of the functional element 15 are exposed upward. A die attachment film or a liquid resin formed of epoxy, polyimide, propylene glycol n-butyl ether, which is hereinafter abbreviated to PNB, polybenzoxazole, which is hereinafter abbreviated to PBO, and the like can suitably be used for the adhesive layer 14. However, the material of the adhesive layer 14 is not limited to those specific examples. In order to improve heat radiation and ground characteristics, silver paste or solder paste is suitably used for the adhesive layer 14. However, the method of forming the adhesive layer 14 is not limited to those specific examples. Furthermore, a spin coating method, a dispensing method, a laminating method, a printing method, and the like can suitably be used to supply the adhesive layer 14. However, the method of supplying the adhesive layer 14 is not limited to those specific examples.

FIG. 2(c) shows a structure obtained by supplying an insulating layer 17 on the structure of FIG. 2(b) and removing the resin around the functional element 15. The resin around the functional element 15 is removed so that no resin is left on the circuit surface of the functional element in order to facilitate control of the height of an insulating layer 18 on the surface of the functional element 15 shown in FIG. 2(d). In order to obtain the structure of FIG. 2(c), the insulating layer 17 is supplied onto the entire surface of the base substrate 11 including the functional element 15 by a spin coating method, a curtain coating method, or a laminating method. In a case where the insulating layer 17 is made of a photosensitive material, the resin of the insulating layer 17 around the functional element 15 is removed by exposure and development. In a case where the insulating layer 17 is made of a non-photosensitive material, resin sheets are used. An opening is formed in the resin sheets at a portion at which the functional element 15 is to be located by a punch, a cutter, or the like. The resin sheets are stacked and cured by a laminator and a pressing machine. Thus, the structure of FIG. 2(c) can be obtained.

FIG. 2(d) is a schematic view showing a cross-sectional structure in which an insulating layer 18 is supplied onto an upper surface of the structure shown in FIG. 2(c). At that time, the insulating layer 18 may be organic or inorganic. Because the surface of the functional element 15 has been kept clean before the supply of the insulating layer 18, the thickness of the insulating layer 18 on the functional element 15 can be made close to a desired value. Therefore, the supply of the insulating layer 18 can be controlled so that the insulating layer 18 becomes thin. Accordingly, via holes 19 can readily be formed above the electrode pads 16, which have been formed on the functional element 15, with a fine inside diameter at a fine arrangement pitch. Nevertheless, some steps are produced on a surface of the insulating layer 18 above the metal pillars 13 and around the functional element 15.

FIG. 2(e) is a schematic cross-sectional view showing that a sacrificial layer 20 is supplied to the structure of FIG. 2(d). Irregularities of the surface of the uppermost layer can be reduced by properly selecting the resin thickness of the sacrificial layer 20. Therefore, the thickness of the entire structure including interconnections formed on the base substrate 11, the insulating layer including the functional element, and the sacrificial layer can readily be measured. At that time, a micrometer, a probe contact device, an ellipsometer, and the like may be used to measure the entire thickness. However, the measurement device is not limited to those specific examples. A grinding or polishing thickness from the upper surface for a subsequent process can be set based on this entire thickness.

FIG. 2(f) is a schematic view showing a cross-sectional structure in which the structure of FIG. 2(e) has been flattened by polishing or grinding. The polishing or grinding exposes the tops of the metal pillars 13 and the tops of the sacrificial layer 20 filled in the via holes 19 on the electrode pads 16 of the functional element 15. The irregularities of the exposed surfaces of the insulating layers 17 and 18, the sacrificial layer 20, and the metal pillar 13 can be reduced to about 5 μm or less. However, the amount of irregularities is not reduced so much because the surface roughness varies depending upon the device being used. According to the present invention, the filled sacrificial layer 20 (may be called a filled relaxation layer) relaxes shearing stress applied to the electrode pads 16 in the polishing or grinding process. Therefore, it is possible to prevent damage to an internal interconnection of the functional element 15. Accordingly, the yield and the reliability of the product can be enhanced.

FIG. 2(g) is a schematic cross-sectional view showing that the sacrificial layer 20 filled in the via holes 19 on the electrode pads 16 of the functional element 15 is removed from the structure of FIG. 2(f). The sacrificial layer 20 can be removed by wet etching using a solvent or the like or dry etching using an etching ratio of the insulating layer 18 and the sacrificial layer 20. Cleaning with an organic solvent or cleaning using oxygen plasma for eliminating a resin residue or the like on the electrode pads 16, which are located at the bottoms of the via holes 19, is effective to prevent deterioration of the yield or electric characteristics in a subsequent interconnection formation process. Furthermore, in order to maintain the reliability, it is also effective to preform a metal film serving as a barrier layer on the electrode pads 16 so that the material of the electrode pads 16 is not influenced by the etching.

FIG. 2(h) is a schematic view showing a cross-sectional structure in which a seed layer 21 for a plating process and a photoresist layer 22 for portions that are not to be plated are formed on the structure of FIG. 2(g). A metal layer is supplied as the seed layer 21 for a plating process onto the entire surface of the structure. Furthermore, a photoresist layer 22 is supplied thereon. The photoresist layer 22 at portions to be plated is removed by exposure and development so as to form a predetermined pattern of an interconnection conductive layer. According to the present invention, since the surface has been flattened by polishing or grinding, discontinuous points are prevented from being generated due to the irregularities at the time of the supply of the seed layer or the formation of the photoresist 22. Therefore, an interconnection can be formed with a high yield in a subsequent process. A laminating method, a spin coating method, a curtain coating method, and the like are suitably used to supply the photoresist layer. However, the method of supplying the photoresist layer is not limited to those specific examples. An electroless plating method, a sputtering method, and the like are suitably used to supply the seed layer. However, the method of supplying the seed layer is not limited to those specific examples. Cu, Ti, Pd, and the like are suitably used for the material of the seed layer. However, the material of the seed layer is not limited to those specific examples. Furthermore, the seed layer 21 may be formed of a single metal layer, multiple metal layers, or a conductive film.

FIG. 2(i) is a schematic view showing a cross-sectional structure in which an interconnection conductive layer 23 is formed on the structure shown in FIG. 2(h) by an electrolytic plating method or an electroless plating method. Cu, Ni, Au, and the like are suitably used for the material of the interconnection conductive layer 23. However, the material of the interconnection conductive layer 23 is not limited to those specific examples. The interconnection conductive layer can be formed by a method other than a plating method, such as a printing method or a lift-off method. According to the present invention, since the surface of the insulating layer has been flattened by grinding or polishing, the interconnection conductive layer 23 can be formed with a high yield. Thus, it is possible to enhance the reliability.

FIG. 2(j) is a schematic view showing a cross-sectional structure in which, after the photoresist 22 is removed from the structure shown in FIG. 2(i), exposed portions of the plating seed layer 21 are removed. Solvents or organic solvents such as isopropyl alcohol, which is hereinafter referred to as IPA, methyl ethyl ketone, which is hereinafter referred to as MEK, ethanol, or acetone are suitably used to remove the photoresist 22. However, the means for removing the photoresist 22 is not limited to those specific examples. Wet etching using an acid solvent or an alkali solvent or dry etching using a plasma etching apparatus can suitably be used to remove the seed layer 21. However, the method of removing the seed layer 21 is not limited to those specific examples. Furthermore, an insulating resin layer may be supplied to the structure of FIG. 2(j), and via holes may be formed in the insulating resin layer. Thus, interconnections may be multilayered as with the semi-additive process of FIG. 1(j). Moreover, solder balls may be formed on the uppermost surface of the conductor so as to produce a packaged product that can be used for flip chip connection.

A method of redistributing a functional element according to the present invention covers a case where the interconnection conductive layer on the base substrate or on the functional element is multilayered, a case where the base substrate is removed, and a case where the base substrate is packaged. Furthermore, the metal pillars are not required if the interconnection layer and the interconnection conductive layer do not need to be connected electrically to each other. The present invention covers the case where no metal pillars are formed.

According to a redistribution method of the present embodiment, an interconnection layer is formed on a base substrate. A metal pillar or a functional element is arranged on the interconnection layer. An insulating layer is formed on the base substrate including the arranged functional element. The insulating layer is removed around the functional element. Furthermore, an insulating layer is formed. A via hole is formed above an electrode pad of the functional element. The insulating layer and a sacrificial layer are flattened in a state in which the via hole is filled with the sacrificial layer. Then the sacrificial layer within the via hole is removed, and an interconnection conductive layer is formed so that the via hole is filled with the interconnection conductive layer. Thus, a redistribution conductive layer is formed. In a polishing or grinding process according to the present invention, a relaxation layer relaxes shearing stress applied to the electrode pad. Therefore, it is possible to prevent damage to an internal interconnection of the functional element. Accordingly, it is possible to provide a functional element product having excellent yield and reliability.

### Third Embodiment

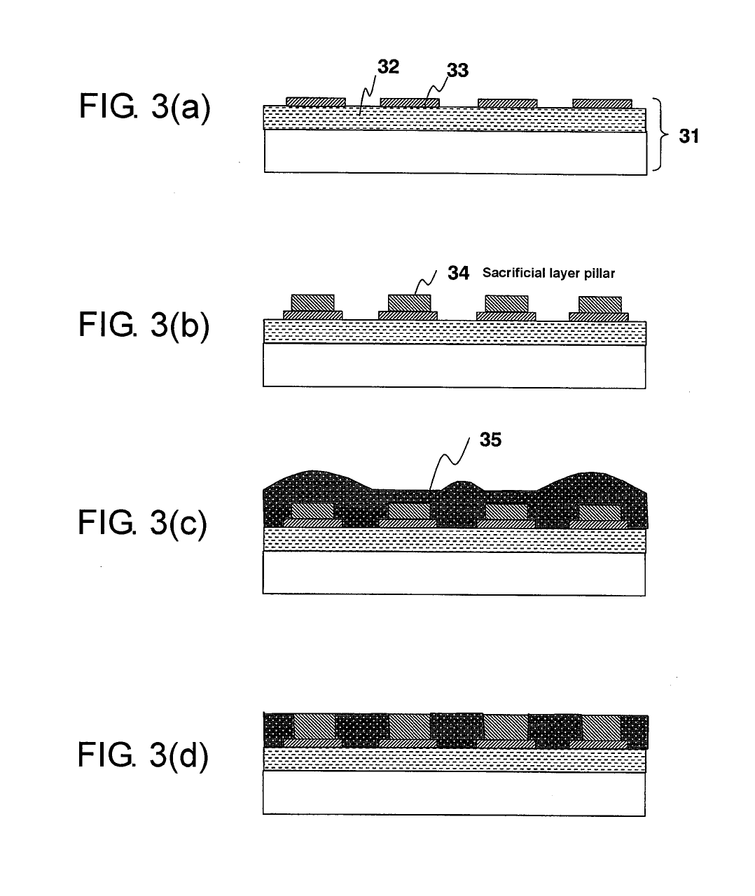

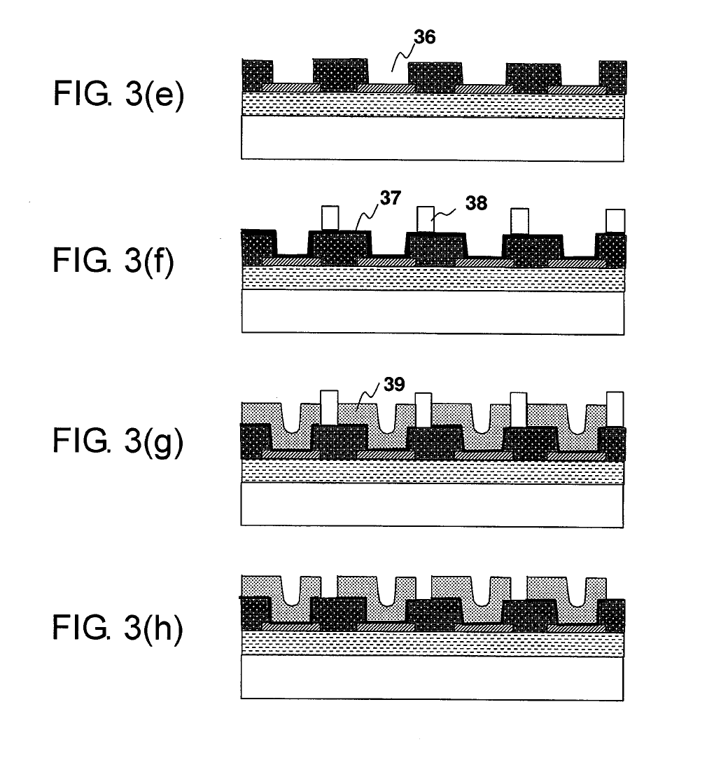

FIGS. 3(a) to 3(d) and 3(e) to 3(h) are schematic cross-sectional views showing processes of a manufacturing method according to a third embodiment of the present invention.

FIG. 3(a) shows a structure which includes a functional element 31, an internal interconnection layer 32 of the functional element, and electrode pads 33 provided on the uppermost layer of the internal interconnection layer 32. In FIG. 3(b), sacrificial layers pillars 34 are made of organic resin. The sacrificial layer pillars are formed on the electrode pads 33. In a case where the sacrificial layer pillars 34 are made of a photosensitive material, the sacrificial layer pillars 34 can be formed by exposure and development. In a case where the sacrificial layer pillars 34 are made of a non-photosensitive material, the sacrificial layer pillars 34 can be formed by a printing method. However, the method of forming the sacrificial layer pillars 34 is not limited to those specific examples. In a case where the sacrificial layer pillars 34 are made of resin, a semi-cured state or a B-stage state is established after exposure and development in order to facilitate removal of the sacrificial layer pillars 34 in a subsequent process. However, the method of forming the sacrificial layer pillars 34 is not limited to those specific examples.

In FIG. 3(c), an insulating layer 35 is formed on the entire surface of the functional element 31 including the sacrificial layer pillars 34. A spin coating method, a curtain coating method, a printing method, a laminating method, and the like are suitably used to supply the insulating layer 35. However, the method of supplying the insulating layer 35 is not limited to those specific examples. Thereafter, the resin of the insulating layer is cured as needed with an oven, a hot plate, or the like. Here, the insulating layer 35 may use an inorganic substance instead of the resin layer. SiO₂, Si₃N₄, SiON, and the like are suitably used for an inorganic insulating layer. However, the inorganic insulating layer is not limited to those specific examples. A spin coating method, a CVD method, a PVD method, and the like are suitably used to supply the insulating layer. However, the method of supplying the insulating layer is not limited to those specific examples. The thickness of the entire structure or the thickness of the insulating layer 35 is measured by using a contact probe, a micrometer, or an ellipsometer.

In a subsequent process of FIG. 3(d), the structure is ground or polished by a predetermined thickness. Thus, an upper portion of the insulating layer 35 is removed from the surface of the structure such that upper surfaces of the sacrificial layer pillars 34 and upper surfaces of the insulating layer 35 around the sacrificial layer pillars 34 are flattened. At that time, a buffing machine, a grinder, a surface planer (grinding machine or cutting machine), a CMP device, and the like are suitably used as a device for polishing or grinding. However, the device for polishing or grinding is not limited to those specific examples.

Subsequently, the sacrificial layer pillars 34 are removed by a solvent or a chemical liquid such that via holes 36 are formed as shown in a cross-sectional structure of FIG. 3(e). A removal method of a wet process using a chemical agent including a solvent component of the sacrificial layer pillars 34 or the like is suitably used to remove the sacrificial layer pillars 34. However, the method of removing the sacrificial layer pillars 34 is not limited to those specific examples. In order to remove a residue of the sacrificial layer pillars 34, it is effective to add an oxygen plasma ashing process for cleaning or the like after the removal process.

FIG. 3(f) shows a cross-sectional structure in which, after a seed layer 37 is formed on the structure of the FIG. 3(e), a photoresist layer 38 is patterned. The seed layer 37 is supplied by a vapor deposition method or an electroless plating method. The photoresist is supplied by a laminating method, a spin coating method, a spray coating method, or the like. Then the photoresist layer 38 is patterned by UV exposure and development. The seed layer 37 is formed of a single layer or multiple layers of metal such as Ti, Cu, and Pd. However, the structure of the seed layer 37 is not limited to those specific examples.

Subsequently, opened portions of the photoresist layer 38 are plated with a metal conductor having a desired thickness by an electrolytic plating method or an electroless plating method. Thus, an interconnection conductive layer 39 is formed as shown in a cross-sectional structure of FIG. 3(g). After the plating process, the photoresist is removed, and the seed layer 37 is etched. Thus, the interconnection conductive layer 39 can be provided on the insulating layer 35 via the seed layer 37 as shown in FIG. 3(h). Thereafter, multiple layers of insulating layers and interconnection conductive layers can alternately be formed so as to form a multilayered interconnection as with FIG. 1(j). Furthermore, a solder resist, a metal bump, or the like may be formed for a final product.

According to a redistribution method of the present embodiment, a sacrificial layer pillar is formed on an electrode pad of a functional element. Furthermore, an insulating layer is formed on the entire surface of the functional element. The insulating layer and the sacrificial layer pillar are flattened. Then the sacrificial layer pillar is removed so as to form a via hole. An interconnection conductive layer is formed so that the via hole is filled with the interconnection conductive layer. Thus, a redistribution conductive layer is formed. In a polishing or grinding process according to the present invention, relaxation layer pillars, namely, sacrificial layer pillars relax shearing stress applied to the electrode pad. Therefore, it is possible to prevent damage to an internal interconnection of the functional element.

Accordingly, it is possible to provide a functional element product having excellent yield and reliability.

### Fourth Embodiment

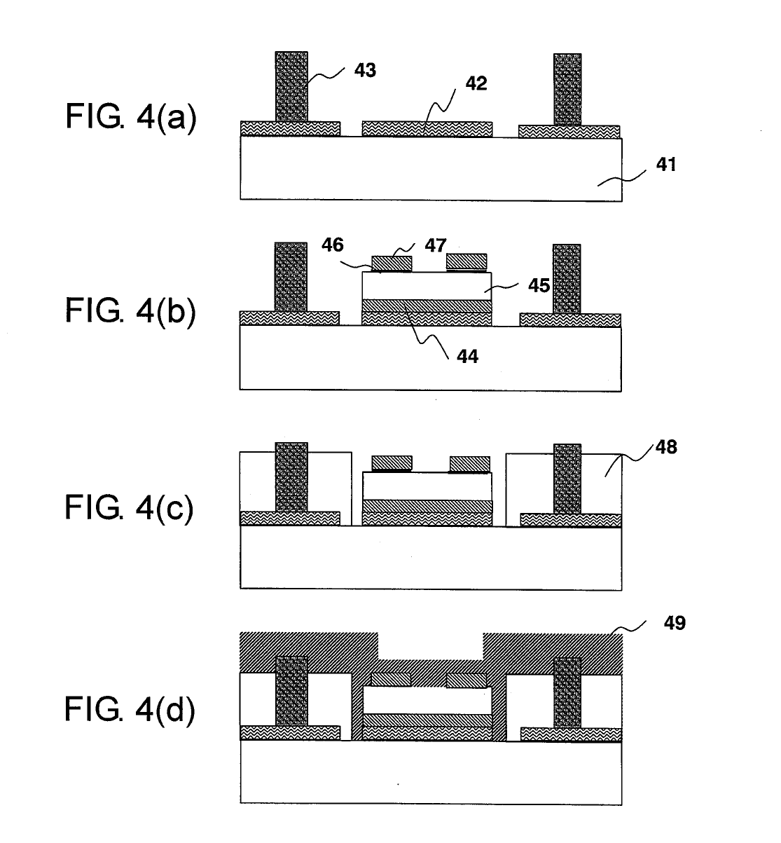

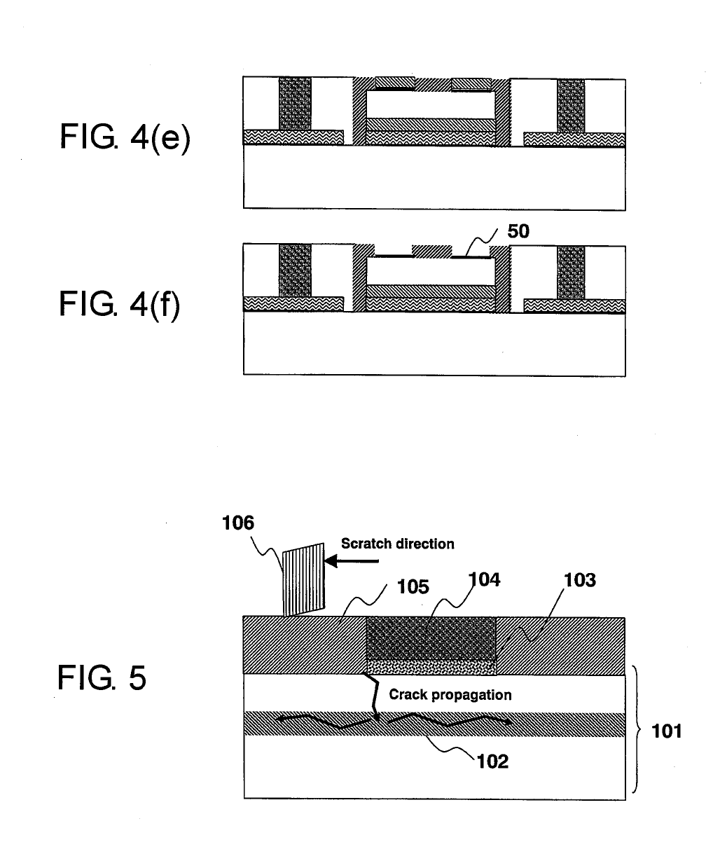

FIGS. 4(a) to 4(d) and FIGS. 4(e), and 4(f) are schematic cross-sectional views showing processes of a manufacturing method according to a fourth embodiment of the present invention.

FIG. 4(a) shows a structure in which, after an interconnection layer 42 is formed on a base substrate 41, metal pillars 43 are formed on the interconnection layer 42. Metals such as Cu and stainless, glass substrates, alumina substrates, Si, and the like are suitably used for the base substrate according to the present invention. However, the material of the base substrate is not limited to those specific examples. Furthermore, from the viewpoint of electric characteristics, it is preferable to provide an insulating layer between the base substrate 41 and the interconnection layer 42 in a case where the base substrate 41 is a conductor or a semiconductor. In a case where the base substrate 41 is a functional element, the metal pillars 43 provided right above electrode pads via the interconnection layer 42 may cause damage to the interior of the functional element. Therefore, it is not preferable to provide the metal pillars 43 right above the electrode pads from the viewpoint of a subsequent grinding or polishing process. Copper, gold, Sn—Ag, Sn, and the like are suitably used for the metal pillars 43. However, the material of the metal pillars 43 is not limited to those specific examples. A method of forming a projecting electrode by plating or heating a gold wire, printing of metal paste, a reflow method, and the like are suitably used as a method of manufacturing the metal pillars 43. However, the method of manufacturing the metal pillars 43 is not limited to those specific examples.

FIG. 4(b) shows a structure in which a functional element 45 is provided at a predetermined position in the structure of FIG. 4(a) via an adhesive layer 44 in a state in which a circuit surface faces upward. In this case, the functional element 45 may not be connected or bonded to the interconnection layer 42 via the adhesive layer 44 and may be connected and bonded directly to the base substrate 41. At that time, electrode pads 46 of the functional element 45 are exposed upward. Furthermore, sacrificial layer pillars 47 are preformed on the electrode pads 46. A die attachment film or a liquid resin formed of epoxy, polyimide, PNB, PBO, and the like can suitably be used for the adhesive layer 44. However, the material of the adhesive layer 44 is not limited to those specific examples. In order to improve heat radiation and ground characteristics, silver paste or solder paste is suitably used for the adhesive layer 44. However, the method of forming the adhesive layer 14 is not limited to those specific examples. Furthermore, a spin coating method, a dispensing method, a laminating method, a printing method, and the like can suitably be used to supply the adhesive layer 44. However, the method of supplying the adhesive layer 44 is not limited to those specific examples.

FIG. 4(c) shows a structure obtained by supplying an insulating layer 48 on the structure of FIG. 4(b) and removing the resin around the functional element 45. The resin around the functional element 45 is removed so that no resin is left on the circuit surface of the functional element in order to facilitate control of the height of an insulating layer 49 on the surface of the functional element 45 shown in FIG. 4(d). In order to obtain the structure of FIG. 4(c), the insulating layer 48 is supplied onto the entire surface of the base substrate 41 including the functional element 45 by a spin coating method, a curtain coating method, or a laminating method. In a case where the insulating layer 48 is made of a photosensitive material, the resin of the insulating layer 48 around the functional element 45 is removed by exposure and development. In a case where the insulating layer 48 is made of a non-photosensitive material, resin sheets are used. An opening is formed in the resin sheets at a portion at which the functional element 45 is to be located by a punch, a cutter, or the like. The resin sheets are stacked and cured by a laminator and a pressing machine. Thus, the structure of FIG. 4(c) can be obtained.

FIG. 4(d) is a schematic view showing a cross-sectional structure in which an insulating layer 49 is supplied onto an upper surface of the structure shown in FIG. 4(c). At that time, the insulating layer 49 may be organic or inorganic. Because the surface of the functional element 45 has been kept clean before the supply of the insulating layer 49, the thickness of the insulating layer 49 on the functional element 45 can be made close to a desired value. Therefore, the supply of the insulating layer 49 can be controlled so that the insulating layer 49 becomes thin. Accordingly, via holes 50 can readily be formed above the electrode pads 46, which have been formed on the functional element 45, with a fine inside diameter at a fine arrangement pitch. Nevertheless, some steps are produced on a surface of the insulating layer 49 above the metal pillars 43 and around the functional element 45.

FIG. 4(e) is a schematic view showing a cross-sectional structure in which the tops of the metal pillars 43 and the tops of the sacrificial layer pillar 47 on the electrode pads 46 of the functional element 45 are exposed in the structure showing in FIG. 4(d). According to the present invention, the sacrificial layer pillars 47 relax shearing stress applied to the electrode pads 46 in the polishing or grinding process. Therefore, it is possible to prevent damage to an internal interconnection of the functional element 45. Accordingly, the yield and the reliability of the product can be enhanced.

FIG. 4(f) is a schematic cross-sectional view showing that the sacrificial layer pillars 47 on the electrode pads 46 of the functional element 45 are removed from the structure shown in FIG. 4(e) by wet etching using a solvent or the like or dry etching using the selectivity of the insulating layers 48 and 49 and the sacrificial layer pillars 47. Cleaning with an organic solvent or cleaning using oxygen plasma for eliminating a resin residue or the like on the electrode pads 46, which are located at the bottoms of the via holes 50, is effective to prevent deterioration of the yield or electric characteristics in a subsequent interconnection formation process. Furthermore, in order to maintain the reliability, it is also effective to preform a metal film serving as a barrier layer on the electrode pads 46 so that the material of the electrode pads 46 is not influenced by the etching.

The schematic cross-sectional view of FIG. 4(f) is the same as FIG. 2(g) of the second embodiment. The processes of FIGS. 2(h) to 2(j) may be performed after the process of FIG. 4(f), so that upper and lower redistribution layers can be formed as viewed in the cross-section of the functional element 45. Furthermore, the present invention covers a case where the interconnections are multilayered by the same process as in FIG. 1(j), a case where the base substrate 41 is removed, and a case where the base substrate 41 is packaged. Additionally, the present invention also covers a case where no metal pillars 43 are formed.

According to a redistribution method of the present embodiment, an interconnection layer is formed on a base substrate. A metal pillar or a functional element having a sacrificial layer pillar formed on an electrode pad is arranged on the interconnection layer. An insulating layer is formed on the base substrate on which the functional element has been arranged. The insulating layer is removed around the functional element. Furthermore, an insulating layer is formed. The insulating layer, the sacrificial layer pillar, and the metal pillar are flattened, and the sacrificial layer pillar on the electrode pad is removed. Then an interconnection conductive layer is formed so that a via hole from which the sacrificial layer pillar has been removed is filled with the interconnection conductive layer. Thus, a redistribution conductive layer is formed. In a polishing or grinding process according to the present invention, a relaxation layer pillar relaxes shearing stress applied to the electrode pad. Therefore, it is possible to prevent damage to an internal interconnection of the functional element. Accordingly, it is possible to provide a functional element product having excellent yield and reliability.

### First Example

A first example of the present invention will be described in detail with reference to the drawings. The details of the first example will specifically be described with reference to FIGS. 1(a) to 1(e) and FIGS. 1(f) to 1(j), which show a manufacturing method according to the first embodiment of the present invention.

FIG. 1(a) is a cross-sectional view showing a structure in which an LSI of a Si substrate was used as a functional element 1 and electrode pads 3 of aluminum (Al) were provided on the uppermost layer of a BEOL layer (Back End Of Line) formed at portions at which transistors were formed, which corresponded to an internal interconnection layer 2 of the functional element 1. The BEOL layer includes a low-k material therein. In a subsequent process, an insulating layer 4 was formed as shown in FIG. 1(b). For example, benzocyclobutene made by the Dow Chemical Company, which is hereinafter abbreviated to BCB, was supplied as the insulating layer 4 with a film thickness of 5 μm to 30 μm by a spin coating method and semi-cured on a hot plate. When BCB was supplied to an 8-inch wafer, then a difference of about 3 μm to about 5 μm in film thickness was produced between an edge of the wafer and a central portion of the wafer. Furthermore, when an insulating material such as polyimide was formed around the electrode pads 3, surface irregularities were produced around the electrode pads depending upon the film thickness of the polyimide in a case where the thickness of BCB was small.

FIG. 1(c) shows a structure in which via holes 5 were formed in the insulating layer 4 in the subsequent process. In the case where the insulating layer 4 is formed of BCB, the via holes 5 can be formed by exposure and development. In view of photosensitive characteristics, a smaller film thickness of resin is effective to form finer via holes 5. The irregularities on the insulating layer 4, which had been produced in the state of FIG. 1(b), were still present after the formation of the via holes 5. Then the BCB was heated and cured with an oven at a temperature of 200° C. to 250° C. for 30 minutes to 120 minutes depending upon the film thickness of the BCB. At that time, due to shrinkage on curing, the surface irregularities became larger than those immediately after the supply of the resin.

Subsequently, in the process of FIG. 1(d), a sacrificial layer 6 was supplied so that the via holes 5 were filled with the sacrificial layer 6. For example, a resist made by Tokyo Ohka Kogyo Co., Ltd. or by AZ Electronic Materials was used for the sacrificial layer 6. A spin coating method was used to supply the sacrificial layer 6. The film thickness of the sacrificial layer 6 was 20 μm to 30 μm. Thereafter, the thickness of the entire structure of the insulating layer 4 and the sacrificial layer 6 formed on the functional element was measured by using an ellipsometer.

The sacrificial layer 6 was ground or polished by a predetermined thickness so as to remove an upper surface of the sacrificial layer 6 such that the remaining BCB had a thickness of 5 μm. Thus, the upper surface was flattened as shown in FIG. 1(e). At that time, for example, the sacrificial layer 6 can be ground with a grinder made by DISCO Corporation. The surface roughness Rₘₐₓ after the grinding was 1 μm or less. With the conventional technique shown in FIG. 5, metal wastes resulting from a metal pillar 104 being ground are scattered on a surface of an insulating layer 105. Thus, a dielectric breakdown resistance is problematic in view of the reliability. However, according to the present invention, since the sacrificial layer 6, which has been provided above the electrode pads, is ground, it is possible to obtain an insulating layer 4 having an excellent insulating property.

The sacrificial layer 6 is formed of resin (resist) and is not formed of metal. Therefore, the hardness of the sacrificial layer 6 is low. Thus, the stress produced during the grinding is relaxed and absorbed by the sacrificial layer 6. Accordingly, the stress produced during the grinding is not transmitted to the interior of the functional element. As a result, it is possible to prevent damage to an internal circuit of the functional element due to the stress. Furthermore, because an abrasive wear of a tip of the grinder (diamond tool) 106 can be reduced, the number of products to be processed by one grinder can be increased. Thus, it is possible to reduce cost for manufacturing products. If the surface roughness is required to be further lowered, the surface is planarized by CMP so as to obtain the surface roughness Rₘₐₓ of 0.5 μm or less.

Subsequently, the sacrificial layer 6 filled in the via holes 5 was removed so that the via holes 5 were opened as in the cross-sectional structure of FIG. 1(f). At that time, a photoresist was used as the sacrificial layer 6. Therefore, the removal method employed a wet process with a solvent component such as MEK, IPA, or ethanol. After the removal of the photoresist, oxygen plasma ashing was conducted to remove a residue on the electrode pads 3.

Next, as shown in the schematic cross-sectional view of FIG. 1(g), a seed layer 7 was supplied onto the structure of FIG. 1(f) by sputtering. Furthermore, a photoresist was supplied by a spin coating method or a spray coating method. Then a photoresist layer 8 was patterned by UV exposure and development after pre-baking at a predetermined temperature. A Ti layer (with a thickness of 10 nm to 50 nm) and a Cu layer (with a thickness of 100 nm to 300 nm) were sequentially sputtered as the seed layer 7. The photoresist had a thickness of 5 μm to 30 μm. A resist made by Tokyo Ohka Kogyo Co., Ltd. or by AZ Electronic Materials was used as the photoresist.

Then, by an electrolytic plating method, opened portions of the photoresist layer 8 were plated with copper having a thickness of 1 μm to 30 μm to thereby form an interconnection conductive layer 9, resulting in the cross-sectional structure of FIG. 1(h). After the plating process, the photoresist was removed by MEK, ethanol, or IPA. The Cu layer and the Ti layer were sequentially etched so as to remove the exposed seed layer. Thus, as shown in FIG. 1(i), the electrode interconnection layer could be provided on the insulating resin layer 4 via the seed layer 7.

Thereafter, a solder resist layer was supplied by a laminator, and Sn solder plating was conducted. The wafer was diced so as to produce individual pieces of LSIs on which redistributed interconnections had been formed. According to the present invention, multiple layers of insulating layers and interconnection conductive layers can alternately be formed so as to form a multilayered interconnection. The above method provided a functional element product having excellent reliability.

FIG. 1(j) is a schematic cross-sectional view showing that an insulating layer 25 and an interconnection conductive layer 26 were formed for further multilayering by using a semi-additive method after the formation of the redistributed interconnections according to the present invention in FIGS. 1(a) to 1(i). BCB was used for the insulating layer 25 and supplied with a thickness of 5 μm to 20 μm by a spin coating method. Then via holes were opened by exposure and development, and a semi-curing process was performed with an oven. Subsequently, a seed layer was formed by sputtering. A photoresist was patterned by exposure and development. Then an interconnection conductive layer 26 was formed by Cu electrolytic plating with a plating thickness of 1 μm to 20 μm. After the electrolytic plating, the photoresist was removed with a solvent, and the seed layer was etched. Thus, the interconnection conductive layer 26 was formed.

According to a method of redistributing a functional element in this example, an insulating resin layer is supplied onto a functional element wafer such as an LSI. The resin on an electrode pad is removed by a dry etching process, a photosensitive process, or a laser, thereby forming a via hole. Subsequently, the interior of the via hole is filled with a sacrificial resin by a spin coating method, a printing method, or a laminating method. Then the top of the insulating resin is exposed by grinding or polishing. At that time, since resin is present on the electrode pad, it is possible to prevent separation produced between the insulating resin and a Cu pillar or between the insulating resin and a gold projecting electrode or breakage of a low-k material, which would be caused by transmission of shearing stress when a conventional pillar or a conventional gold projecting electrode is used. Simultaneously, it is possible to prevent grinding wastes from entering into the via hole. Furthermore, a surface of the insulating resin layer is flattened. Then the sacrificial layer resin within the via hole is removed by a solvent, heat, or UV radiation. A plating seed layer is formed, and a plating resist pattern is formed. Then electrolytic plating is conducted. At that time, a fine interconnection pattern can be formed on a flat surface of the resin around the via hole. The resist is removed, and the seed layer is etched. Thus, a redistribution layer is formed from the electrode pad.

According to a method of redistributing a functional element in this example, a sacrificial layer of a resist is present on an electrode pad during a grinding or polishing process. Therefore, shearing stress can be relaxed so as to prevent damage of an internal circuit of the functional element. Thus, it is possible to form a fine interconnection conductive layer that can prevent breakage of the interior of the functional element, has excellent reliability and a high yield, and can achieve a high level of flatness.

### Second Example

A second example of the present invention will be described in detail with reference to the drawings. The details of the second example will specifically be described with reference to FIGS. 2(a) to 2(e) and 2(f) to 2(j), which show a manufacturing method according to the second embodiment of the present invention.

FIG. 2(a) is a view showing a structure in which, after a copper interconnection layer 12 was formed on a base substrate 11 with a thickness of 1 μm to 5 μm, Cu metal pillars 13 were formed on the interconnection layer 12 with a height of 10 μm to 50 μm. An 8-inch wafer or a 12-inch wafer of Si having a SiO₂ layer formed between the interconnection layer 12 and the wafer was used as the base substrate. In a case where transistors are also formed inside of the base substrate, a design in which metal (Cu) pillars 13 are formed right above the electrode pads via the interconnection layer 12 is avoided such that damage of the base substrate can be prevented in a subsequent grinding process.

Subsequently, a functional element 15 having a thickness of 8 μm to 20 μm was mounted on a predetermined location of the interconnection layer 12, at which an alignment mark had been formed on the structure of FIG. 2(a), via an adhesive layer 14 in a state in which a circuit surface faced upward. Thus, the cross-sectional structure shown in FIG. 2(b) was formed. At that time, an LSI and an integrated passive device (IPD) were used for the functional element 15. From the viewpoint of a subsequent grinding or polishing process, it is preferable for the functional element 15 to have a thickness smaller than that of the Cu pillars 13. The functional element 15 and the Cu pillars 13 were provided on the same base substrate 11.

For heat radiation, the copper interconnection layer 12 was formed right below the functional element being mounted, so that heat was diffused into a wide area on the base substrate. For elements having a low calorific value, such as an IPD, no interconnection layer 12 was formed between the base substrate 11 and the adhesive layer 14. Thus, the base substrate 11 may be connected directly to the functional element 11 via the adhesive layer 14. At that time, electrode pads 16 of the functional element 15 were exposed upward. The adhesive layer 14 was supplied onto the base substrate 11 by a spin coating method. BCB made by the Dow Chemical Company for removing resin at locations other than locations requiring an adhesive by exposure and development or the LE series made by Lintec Corporation with a thickness of 15 μm that had been laminated on a rear face of the functional element 15 being mounted was used for the adhesive layer 14. The adhesive was selected depending upon the thickness of the functional element and the thickness of the Cu pillars.

FIG. 2(c) is a view showing that, after an insulating layer 17 was supplied onto the structure of FIG. 2(b), the insulating layer 17 around the functional element 15 was removed. The insulating layer 17 around the functional element 15 was removed so that no resin was left on the circuit surface of the functional element in order to facilitate control of the height of an insulating layer 18 on the surface of the functional element 15 shown in FIG. 2(d). In order to obtain the structure of FIG. 2(c), BCB made by the Dow Chemical Company, resin of the HD series made by HD MicroSystems, Ltd., or resin of the CRC series made by Sumitomo Bakelite Co., Ltd. was used for the insulating layer 17. The resin was supplied onto the entire surface of the base substrate 11 including the functional element 15 by a spin coating method. Then the resin around the functional element 15 was removed by UV exposure and development.

If the resin has a low viscosity and the functional element has a thickness of 10 μm or larger, the structure of FIG. 2(c) can be obtained by repeating spin coating and exposure and development more than once. The insulating layer 17 does not need to be formed of a single layer of the same resin and may have a multilayered structure having multiple layers of different resins. In the state of FIG. 2(c), the resin of the insulating layer 17 surrounded surfaces of the Cu pillars 13 at portions that were located higher than the height of the insulating layer 17, which was located around the Cu pillars 13.

FIG. 2(d) is a schematic view showing a cross-sectional structure in which an insulating layer 18 was supplied onto an upper surface of the structure of FIG. 2(c). At that time, the insulating layer 18 may be organic or inorganic as with the insulating layer 17. A SiO₂ layer and a Si₃N₄ layer were deposited as inorganic material by a plasma-enhanced chemical vapor deposition method, which is hereinafter abbreviated to a PECVD method. However, the length of the process time becomes problematic with a speed of the vapor deposition in a case where the film thickness is equal to or larger than 5 μm. Therefore, in such a case, BCB made by the Dow Chemical Company, the HD series made by HD MicroSystems, Ltd., or the CRC series made by Sumitomo Bakelite Co., Ltd. was used and supplied by a spin coating method. When an inorganic material was used, an organic or metal mask material was further supplied, and via holes 19 having a fine inside diameter and an arrangement pitch were formed above the electrode pads 16, which had been formed on the functional element 15, by dry etching. When an organic material was used, via holes 19 were formed by a laser and dry etching using a mask material in a case of a non-photosensitive resin. In a case of a photosensitive resin, the via holes 19 were formed by exposure and development. Here, some steps were produced on an upper surface of the insulating layer 18 above the Cu pillars 13 and around the functional element 15.

FIG. 2(e) is a schematic cross-sectional view showing that a sacrificial layer 20 was supplied onto the structure shown in FIG. 2(d). A photoresist made by Tokyo Ohka Kogyo Co., Ltd. or by AZ Electronic Materials was used for the sacrificial layer 20. Irregularities on a surface of the uppermost layer of the photoresist can be reduced by selecting the thickness of the resin depending upon the surface irregularities of the insulating layer 18. Therefore, the thickness of the photoresist was selected at 20 μm. The thickness of the entire structure formed up to the sacrificial layer above the base substrate 11 was measured at several points of the wafer with a prober.

FIG. 2(f) is a schematic view showing a cross-sectional structure in which the tops of the Cu pillars 13 and the tops of the sacrificial layer 20 filled in the via holes 19 above the electrode pads 16 of the functional element 15 were exposed by grinding or polishing the structure shown in FIG. 2(e). In the case where the insulating layer 18 was organic, a grinding apparatus made by DISCO Corporation was used. In the case where the insulating layer 18 was inorganic, a grinder was used. The irregularities of the exposed surfaces of the insulating layers 17 and 18, the sacrificial layer 20, and the Cu pillars 13 can be reduced to about 5 μm or less by the device being used. However, the amount of irregularities is not reduced so much because the surface roughness varies depending upon the device being used or a combination of the materials.

According to the present invention, the filled sacrificial layer 20 relaxes shearing stress applied to the electrode pads 16 in the polishing or grinding process. Therefore, it is possible to prevent damage to an internal interconnection of the functional element 15. Accordingly, the yield and the reliability of the product can be enhanced.

FIG. 2(g) is a schematic cross-sectional view showing that the sacrificial layer 20 filled in the via holes 19 on the electrode pads 16 of the functional element 15 was wet-etched with MEK, ethanol, IPA, or the like in the structure of FIG. 2(f).

FIG. 2(h) is a schematic view showing a cross-sectional structure in which a seed layer 21 for a plating process and a photoresist layer 22 were formed on the structure of FIG. 2(g). A Ti layer (with a thickness of 10 nm to 50 nm) and a Cu layer (with a thickness of 100 nm to 300 nm) were sequentially sputtered as metal layers of the seed layer 21. Furthermore, the thickness of the photoresist was 5 μm to 30 μm. A resist made by Tokyo Ohka Kogyo Co., Ltd. or by AZ Electronic Materials was used for the photoresist. After the photoresist layer 22 was supplied, the photoresist layer was removed from portions to be plated by exposure and development, so that a predetermined pattern for an interconnection conductive layer was formed. A laminating method was used to supply the photoresist layer. According to the present invention, since the surface had been flattened by polishing or grinding, discontinuous points were prevented from being generated due to the irregularities at the time of the supply of the seed layer or the formation of the photoresist 22. Therefore, interconnections could be formed with a high yield in a subsequent process.

FIG. 2(i) is a schematic view showing a cross-sectional structure in which a copper interconnection conductive layer 23 was formed on the structure shown in FIG. 2(h) with a thickness of 1 μm to 10 μm by an electrolytic plating method. Since the surface to be plated had been flattened by grinding or polishing, the plating process could be performed with a high yield. Thus, it was possible to prevent open defects due to the surface irregularities even with copper-plated interconnections having a width of 10 μm or less.

FIG. 2(j) is a schematic view showing a cross-sectional structure in which, after the photoresist 22 was removed from the structure shown in FIG. 2(i) with IPA, MEK, or ethanol, the Cu layer and the Ti layer of the plating seed layer 21 were sequentially removed with a mixed acid and an alkali solution. Furthermore, an insulating resin layer may be supplied to the structure of FIG. 2(j), and via holes may be formed. Thus, interconnections may be multilayered as with the semi-additive process of FIG. 1(j). Moreover, solder balls may be formed on the uppermost surface of the conductor so as to produce a packaged product that can be used for flip chip connection.

According to a method of manufacturing a substrate including a functional element in this example, an interconnection layer and a metal pillar are preformed on a base substrate. If the base substrate is a functional element, the metal pillar is not provided directly on an electrode pad and is provided at a different position connected to the electrode pad by using a method of redistributing a functional element in this example. A functional element is mounted on the base substrate in a state in which a circuit element surface faces upward. The functional element and the metal pillar on the base substrate are embedded in an insulating resin layer. At that time, patterning is conducted so that the resin does not enter into a location of the functional element when a photosensitive resin or a printing method is used. Next, an insulating resin layer is supplied onto the functional element. At that time, since there has been no resin on the functional element, the film thickness of the resin can be controlled flexibly. The resin on the electrode pad of the functional element is removed by exposure and development or the like in a case where the resin is photosensitive or by dry etching or a laser in a case where the resin is non-photosensitive. Thus, a via hole is formed.

Then a sacrificial layer resin is supplied into the via hole. The top of the insulating resin and the top of the metal pillar are exposed by grinding or polishing. At that time, since there is resin on the electrode pad of the functional element, it is possible to prevent breakage of a brittle material such as a low-k material in the functional element due to transmission of stress. Furthermore, it is also possible to prevent grinding wastes from entering into the via hole. Moreover, a surface of the resin can be flattened. The sacrificial layer within the via hole is removed. A plating seed layer is formed, and a pattern of a plating resist is formed. Then electrolytic plating is conducted. A fine interconnection pattern can be formed on a flat surface of the resin around the via hole. The resist is removed, and the seed layer is etched. Thus, it is possible to form an interconnection conductive layer on the insulating resin that interconnects the exposed electrode pad of the functional element, the metal pillar, and the interconnection layer of the base substrate.

According to this example, shearing stress produced in a flattening process is relaxed by the sacrificial layer. Therefore, it is possible to form a fine interconnection conductive layer that can prevent breakage of the interior of the functional element, has excellent reliability and a high yield, and can achieve a high level of flatness.

### Third Example

A third example of the present invention will be described in detail with reference to the drawings. The details of the third example will specifically be described with reference to FIGS. 3(a) to 3(d) and 3(e) to 3(h), which show a manufacturing method according to the third embodiment of the present invention.

FIG. 3(a) shows a structure of an internal interconnection layer 32 of a functional element 31 and electrode pads 33 of Al that were provided on the uppermost layer of the internal interconnection layer 32 in a case where an LSI was used as the functional element 31. In FIG. 3(b), sacrificial layer pillars 34 having a height of 20 μm to 30 μm were formed on part of the electrode pads 33 with BCB made by the Dow Chemical Company. The sacrificial layer pillars 34 were formed on the electrode pads 33 by exposure and development. In FIG. 3(c), Si₃N₄ was supplied as an insulating layer 35 at a vapor deposition temperature of 150° C. until the thickness became 40 μm by a PECVD method. Then the thickness of the insulating layer 35 of Si₃N₄ was measured by an ellipsometer.

In a subsequent process of FIG. 3(d), an upper surface of the insulating layer 35 was ground with a grinder by a thickness of 20 μm. Thus, upper surfaces of the sacrificial layer pillars 34 and an upper surface of the insulating layer 35 were flattened. The upper surfaces of the sacrificial layer pillars 34 of BCB and the upper surface of the insulating layer 35 of Si₃N₄ around the sacrificial layer pillars 34 were flattened to have a surface roughness equal to or less than Rₘₐₓ. Subsequently, the sacrificial layer pillars 34 were removed by wet etching using a solvent so as to form the cross-sectional structure of FIG. 3(e) in which via holes 36 were formed above the electrode pads 33. After the removal of the sacrificial layer pillars 34, a residue was removed by an oxygen plasma ashing process for cleaning.

Next, as shown in FIG. 3(f), there was formed a cross-sectional structure in which, after a seed layer 37 was formed on the structure of FIG. 3(e), a photoresist layer 38 was patterned. The seed layer 37 was formed by sequentially sputtering a Ti layer (with a thickness of 10 nm to 50 nm) and a Cu layer (with a thickness of 100 nm to 300 nm). A resist made by Tokyo Ohka Kogyo Co., Ltd. or by AZ Electronic Materials was used for a photoresist, which was supplied by a spin coating method. The photoresist layer 38 was patterned by UV exposure and development. Subsequently, opened portions of the photoresist layer 38 were plated with a metal conductor having a thickness of 1 μm to 10 μm by a copper electrolytic plating method. Thus, an interconnection conductive layer 39 was formed as shown in a cross-sectional structure of FIG. 3(g).

After the electrolytic plating process, the photoresist 38 was removed with a solvent, and the seed layer 37 of Ti and Cu was etched with acid or alkali solution. Thus, the cross-sectional structure of FIG. 3(h) was formed. As shown in FIG. 3(h), a copper interconnection conductive layer 39 could be provided on the insulating layer 35 of Si₃N₄ via the seed layer 37. Then multiple insulating layers and interconnection conductive layers were alternately formed. Adjacent interconnection conductive layers were connected to each other by Cu via holes. Thus, a multilayered interconnection was formed. Furthermore, a solder resist, a metal bump, or the like was formed for a final product. With the above method, a functional element product having excellent reliability was manufactured.

According to a method of redistributing a functional element in this example, an insulating resin layer is provided on a functional element wafer such as an LSI. A sacrificial layer pillar of resin is formed on an electrode pad by a photosensitive process or a laser. Then an insulating resin is supplied. The top of the sacrificial layer pillar is exposed by grinding or polishing. At that time, since resin is present on the electrode pad, it is possible to prevent separation produced between the insulating resin and a Cu pillar or between the insulating resin and a gold projecting electrode or breakage of a low-k material, which would be caused by transmission of shearing stress when a conventional pillar or a conventional gold projecting electrode is used. Simultaneously, it is possible to prevent grinding wastes from entering into the via hole. Furthermore, a surface of the insulating resin layer is flattened. Then the sacrificial layer resin within the via hole is removed by a solvent, heat, UV radiation, dry etching, or the like. A plating seed layer is formed, and a plating resist pattern is formed. Then electrolytic plating is conducted. At that time, a fine interconnection pattern can be formed on a flat surface of the resin around the via hole. The resist is removed, and the seed layer is etched. Thus, a redistribution layer is formed from the electrode pad. It is possible to form a conductive interconnection at a high density with excellent reliability.

### Fourth Example

A fourth example of the present invention will be described in detail with reference to the drawings. FIGS. 4(a) to 4(d) and 4(e) and 4(f) show a manufacturing method according to the fourth example of the present invention.

FIG. 4(a) is a view showing a structure in which, after a copper interconnection layer 42 was formed on a base substrate 41 with a thickness of 1 μm to 5 μm, Cu metal pillars 43 were formed on the interconnection layer 42 with a height of 10 μm to 50 μm. An 8-inch wafer or a 12-inch wafer of Si having a SiO₂ layer formed between the interconnection layer 42 and the wafer was used as the base substrate. In a case where transistors are also formed inside of the base substrate, a design in which Cu pillars 43 are formed right above the electrode pads via the interconnection layer 42 is avoided such that damage of the base substrate can be prevented in a subsequent grinding process.

Subsequently, a functional element 45 having a thickness of 8 μm to 20 μm was mounted on a predetermined location of the interconnection layer 42, at which an alignment mark had been formed on the structure of FIG. 4(a), via an adhesive layer 44 in a state in which a circuit surface faced upward. Thus, the cross-sectional structure shown in FIG. 4(b) was formed. At that time, an LSI, an MEMS device, and an IPD were used for the functional element 45. From the viewpoint of a subsequent grinding or polishing process, it is preferable for the functional element 45 to have a thickness smaller than that of the Cu pillars 43. The functional element 45 and the Cu pillars 43 were provided on the same base substrate 41. For heat radiation, the copper interconnection layer 42 was formed right below the functional element being mounted, so that heat was diffused into a wide area on the base substrate. For elements having a low calorific value, such as an IPD or an MEMS, no interconnection layer 42 was formed between the base substrate 41 and the adhesive layer 44. Thus, the functional element 41 was connected directly to the base substrate 41 via the adhesive layer 44.

At that time, sacrificial layer pillars 47 preformed on electrode pads 46 of the functional element 45 faced upward. The adhesive layer 44 was supplied onto the base substrate 41 by a spin coating method. BCB made by the Dow Chemical Company for removing resin at locations other than locations requiring an adhesive by exposure and development or the LE series made by Lintec Corporation with a thickness of 15 μm to 20 μm that had been laminated on a rear face of the functional element 45 being mounted was used for the adhesive layer 14. The thickness and material of the adhesive were selected depending upon the thickness of the functional element and the thickness of the Cu pillars.

FIG. 4(c) is a view showing a cross-sectional structure obtained by supplying an insulating layer 48 onto the structure of FIG. 4(b) and removing resin of the insulating layer 48 around the functional element 45. The insulating layer 48 around the functional element 45 was removed so that no resin was left on the circuit surface of the functional element in order to facilitate control of the height of an insulating layer 48 on the surface of the functional element 45 shown in FIG. 4(d). In FIG. 4(c), BCB made by the Dow Chemical Company, the HD series made by HD MicroSystems, Ltd., or the CRC series made by Sumitomo Bakelite Co., Ltd. was used for the insulating layer 48. An insulating layer 48 was supplied onto the entire surface of the base substrate 41 including the functional element 45 by a spin coating method. Then the resin around the functional element 45 was removed by UV exposure and development.

If the resin has a low viscosity and the functional element has a thickness of 10 μm or larger, the structure of FIG. 4(c) can be obtained by repeating spin coating and exposure and development more than once. The insulating layer 48 does not need to be formed of a single layer of the same resin and may have a multilayered structure having multiple layers of different resins. In the state of FIG. 4(c), the resin of the insulating layer 48 surrounded surfaces of the Cu pillars 43 at portions that were located higher than the height of the insulating layer 48, which was located around the Cu pillars 13.

FIG. 4(d) is a schematic view showing a cross-sectional structure in which an insulating layer 49 was further supplied onto an upper surface of the structure of FIG. 4(c). At that time, the insulating layer 49 may be organic or inorganic as with the insulating layer 48. A SiO₂ layer and a Si₃N₄ layer were deposited as the insulating layer 49 with a thickness of 5 μm to 10 μm by a PECVD method. Here, some steps were produced on an upper surface of the insulating layer 49 above the Cu pillars 43 and around the functional element 45.

FIG. 4(e) is a schematic view showing a cross-sectional structure in which the tops of the sacrificial layer pillars 47 on the electrode pads 46 of the functional element 45 were exposed by polishing or grinding the structure shown in FIG. 4(d). According to the present invention, the sacrificial layer pillars 47 relaxes shearing stress applied to the electrode pads 46 in the polishing or grinding process. Therefore, it is possible to prevent damage to an internal interconnection of the functional element 45. Accordingly, the yield and the reliability of the product can be enhanced.

FIG. 4(f) is a schematic cross-sectional view showing that the sacrificial layer pillars 47 on the electrode pads 46 of the functional element 45 were removed by wet etching with a solvent or the like in the structure of FIG. 4(e). Cleaning with an organic solvent or cleaning using oxygen plasma for eliminating a resin residue or the like on the electrode pads 46, which were located at the bottoms of the via holes 50, is effective to prevent deterioration of the yield or electric characteristics in a subsequent interconnection formation process. Furthermore, in order to maintain the reliability, it is also effective to preform a metal film serving as a barrier layer on the electrode pads 46 so that the material of the electrode pads 46 is not influenced by the etching. The schematic cross-sectional view of FIG. 4(f) is the same as FIG. 2(g). The processes of FIGS. 2(h) to 2(j) may be performed after the process of FIG. 4(f), so that upper and lower redistribution layers can be formed as viewed in the cross-section of the functional element 45.

In a method of redistributing a functional element according to the present invention, there is illustrated an example in which the processes of FIGS. 2(h) to 2(j) are performed in addition to the processes of FIGS. 4(a) to 4(d), 4(e), and 4(f). Furthermore, a manufacturing method of the present invention covers a case where the interconnections are multilayered, a case where the base substrate is removed, and a case where the base substrate is packaged. Additionally, the present invention also covers a case where no metal pillars 43 are formed.

According to this example, shearing stress produced in a flattening process is relaxed by the sacrificial layer pillars. Therefore, it is possible to form a fine interconnection conductive layer that can prevent breakage of the interior of the functional element, has excellent reliability and a high yield, and can achieve a high level of flatness.

According to a method of redistributing a functional element of the present invention, an insulating resin layer is supplied onto a functional element wafer such as an LSI. The resin on an electrode pad is removed by a dry etching process, a photosensitive process, or a laser, thereby forming a via hole. Subsequently, the interior of the via hole is filled with a sacrificial layer by a spin coating method, a printing method, or a laminating method. Then the top of the insulating resin is exposed by grinding or polishing. At that time, since resin is present on the electrode pad, it is possible to prevent separation produced between the insulating resin and a Cu pillar or between the insulating resin and a gold projecting electrode or breakage of a low-k material, which would be caused by transmission of shearing stress when a conventional pillar or a conventional gold projecting electrode is used. Simultaneously, it is possible to prevent grinding wastes from entering into the via hole. Furthermore, a surface of the insulating resin layer is flattened. Then the sacrificial layer resin within the via hole is removed by a solvent, heat, or UV radiation. A plating seed layer is formed, and a plating resist pattern is formed. Then electrolytic plating is conducted. At that time, a fine interconnection pattern can be formed on a flat surface of the resin around the via hole. The resist is removed, and the seed layer is etched. Thus, a redistribution layer is formed from the electrode pad.

According to a method of manufacturing a substrate including a functional element of the present invention, an interconnection and a metal pillar are preformed on a base substrate. If the base substrate is a functional element, the metal pillar is not provided directly on an electrode pad and is provided at a different position connected to the electrode pad by using a method of redistributing a functional element in this example. A functional element is mounted on the base substrate in a state in which a circuit element surface faces upward. The functional element and the metal pillar on the base substrate are embedded in an insulating resin. At that time, patterning is conducted so that the resin does not enter into a location of the functional element when a photosensitive resin or a printing method is used. Next, an insulating resin is supplied onto the functional element. At that time, since there has been no resin on the functional element, the film thickness of the resin can be controlled flexibly. The resin on the electrode pad of the functional element is removed by exposure and development or the like in a case where the resin is photosensitive or by dry etching or a laser in a case where the resin is non-photosensitive. Thus, a via hole is formed. Then a sacrificial layer resin is supplied into the via hole. The top of the insulating resin and the top of the metal pillar are exposed by grinding or polishing.

At that time, since there is resin on the electrode pad of the functional element, it is possible to prevent breakage of a brittle material such as a low-k material in the functional element due to transmission of stress. Furthermore, it is also possible to prevent grinding wastes from entering into the via hole. Moreover, a surface of the resin can be flattened. The sacrificial layer within the via hole is removed. A plating seed layer is formed, and a pattern of a plating resist is formed. Then electrolytic plating is conducted. A fine interconnection pattern can be formed on a flat surface of the resin around the via hole. The resist is removed, and the seed layer is etched. Thus, it is possible to form an interconnection conductive layer on the insulating resin that connects the electrode pad of the functional element and the base substrate to the exposed metal pillar.

According to a method of redistributing a functional element of the present invention, an insulating resin layer is provided on a functional element wafer such as an LSI. A sacrificial layer pillar of resin is formed on an electrode pad by a photosensitive process or a laser. Then an insulating resin is supplied. The top of the sacrificial layer pillar is exposed by grinding or polishing. At that time, since resin is present on the electrode pad, it is possible to prevent separation produced between the insulating resin and a Cu pillar or between the insulating resin and a gold projecting electrode or breakage of a low-k material, which would be caused by transmission of shearing stress when a conventional pillar or a conventional gold projecting electrode is used. Simultaneously, it is possible to prevent grinding wastes from entering into the via hole. Furthermore, a surface of the insulating resin layer is flattened. Then the sacrificial layer resin within the via hole is removed by a solvent, heat, UV radiation, dry etching, or the like. A plating seed layer is formed, and a plating resist pattern is formed. Then electrolytic plating is conducted. At that time, a fine interconnection pattern can be formed on a flat surface of the resin around the via hole. The resist is removed, and the seed layer is etched. Thus, a redistribution layer is formed from the electrode pad. It is possible to form a conductive interconnection at a high density with excellent reliability.

Although the preferred embodiments of the present invention have been described above, the present invention is not limited to those embodiments. It should be understood that various changes and modifications may be made therein without departing from the scope of the present invention.

This application is based upon and claims the benefit of priority from Japanese patent application No. 2010-133785, filed on Jun. 11, 2010, the disclosure of which is incorporated herein in its entirety by reference.

### DESCRIPTION OF REFERENCE NUMERALS

1, 15, 31, 45 Functional element
2, 32 Internal interconnection layer
3, 16, 33, 46 Electrode pad
4, 17, 18, 25, 35, 48, 49 Insulating layer
5, 19, 36, 50 Via hole
6, 20 Sacrificial layer
7, 21, 37 Seed layer
8, 22, 38 Photoresist layer
9, 23, 26, 39 Interconnection conductive layer
11, 41 Base substrate
12, 42 Interconnection layer
13, 43 Metal pillar
14, 44 Adhesive layer
34, 47 Sacrificial layer pillar
101 Functional element (LSI)
102 Low-k layer
103 Electrode pad
104 Metal pillar (projecting electrode)
105 Insulating layer
106 Grinder (diamond tool)

1. A method of redistributing a functional element, the method comprising:
forming an insulating layer on a functional element and then forming a via hole in the insulating layer for thereby forming a via hole on an electrode pad of the functional element;
filling the via hole with a sacrificial layer;
flattening a surface above the functional element so as to expose the sacrificial layer in the via hole;
removing the sacrificial layer in the via hole so as to expose the electrode pad in the via hole; and
connecting an interconnection conductive layer to the exposed electrode pad in the via hole.

2. The method of redistributing a functional element as described in claim 1, further comprising:
preparing a base substrate;
forming at least one interconnection layer on the base substrate; and
mounting the functional element on the base substrate;
wherein:
the insulating layer is performed after the functional element is mounted on the base station and is formed on the base substrate including the mounted functional element and the via hole is then formed on the electrode pad of the functional element in the insulating layer; and
wherein:
the sacrificial layer is filled with the via hole formed on the electrode pad of the functional element.

3. The method of redistributing a functional element as described in claim 2, further comprising:
forming a second insulating layer and then forming an opening portion in the second insulating layer around the mounted functional element after the functional element is mounted on the base substrate and before the insulating layer is formed.

4. The method of redistributing a functional element as described in claim 3, further comprising:
forming a metal pillar on the base substrate after the at least one interconnection layer is formed on the base substrate and before the functional element is mounted on the base substrate,
wherein:
the flattening includes simultaneously exposing a top of the metal pillar in the second insulating layer.

5. A method of redistributing a functional element, the method comprising:
forming a sacrificial layer pillar on an electrode pad of a functional element;
forming an insulating layer on an entire surface of the functional element including the sacrificial layer pillar;
flattening a surface of the insulating layer so as to expose the sacrificial layer pillar;
removing the exposed sacrificial layer pillar so as to form a via hole on the electrode pad; and
connecting an interconnection conductive layer to the electrode pad of the functional element via the via hole.

6. A method of redistributing a functional element, the method comprising:
forming at least one interconnection layer on a base substrate;
forming a sacrificial layer pillar on an electrode pad of a functional element;
mounting the functional element on which the sacrificial layer pillar has been formed on the base substrate;
forming an insulating layer on the base substrate so as to cover the mounted functional element;
flattening a surface of the insulating layer so as to expose the sacrificial layer pillar;
removing the exposed sacrificial layer pillar so as to expose the electrode pad; and
connecting a interconnection conductive layer to the exposed electrode pad of the functional element.

7. The method of redistributing a functional element as described in claim 6, further comprising:
forming a second insulating layer and then forming an opening portion in the second insulating layer around the mounted functional element after the functional element is mounted on the base substrate and before the insulating layer is formed on the base station.

8. The method of redistributing a functional element as described in claim 7, further comprising:
forming a metal pillar on the base substrate after the at least one interconnection layer is formed on the base substrate and before the sacrificial layer pillar is formed on the electrode pad of the functional element,
wherein the flattening includes simultaneously exposing a top of the metal pillar in the second insulating layer.

9. The method of redistributing a functional element as described in claim 5, wherein the sacrificial layer pillar is formed of semi-cured resin in a B stage.

10. The method of redistributing a functional element as described in claim 5, wherein the sacrificial layer pillar is formed of resin, and the insulating layer covering the sacrificial layer pillar is formed of inorganic substance.

11. The method of redistributing a functional element as described in claim 1, wherein the insulating layer is formed of an inorganic material.

12. The method of redistributing a functional element as described in claim 1, wherein the insulating layer is formed of an organic material.

13. The method of redistributing a functional element as described in claim 1, wherein at least one intermediate insulating layer and at least one upper interconnection conductive layer are repeatedly provided above the interconnection conductive layer to form a multilayered interconnection structure.

14. The method of redistributing a functional element as described in claim 13, wherein, in a case where resin is used for the insulating layer and the intermediate insulating layer, baking is carried out under a semi-curing condition during formation of each of the resin insulating layers, and main curing is carried out after formation of the last resin insulating layer in all steps.

15. The method of redistributing a functional element as described in claim 6, wherein the sacrificial layer pillar is formed of semi-cured resin in a B stage.

16. The method of redistributing a functional element as described in claim 6, wherein the sacrificial layer pillar is formed of resin, and the insulating layer covering the sacrificial layer pillar is formed of inorganic substance.
